(19) United States
(12) Patent Application Publication
(10) Pub. No.: US 2012/0282726 A1
(43) Pub. Date: Nov. 8, 2012

(54) METHOD FOR FORMING THIN SEMICONDUCTOR LAYER SUBSTRATES FOR MANUFACTURING SOLAR CELLS

(75) Inventors: Rolf Brendel, Hameln (DE); Marco Ernst, Hameln (DE)

(73) Assignee: INSTITUT FÜR SOLARENERGIE-FORSCHUNG GMBH, Emmerthal (DE)

(21) Appl. No.: 13/509,567

(22) PCT Filed: Nov. 11, 2010
(86) PCT No.: PCT/EP2010/067299

§ 371 Date: Jul. 10, 2012

(30) Foreign Application Priority Data
Nov. 13, 2009 (DE) 10 2009 053 262.5

(51) Int. Cl. H01L 31/18

(52) U.S. Cl. 438/73; 257/E31.001

(57) ABSTRACT

Described is a method for forming thin semiconductor layer substrates for manufacturing solar cells, in which method in a provided semiconductor substrate alternately macroporous layers of low macroporosity and etched-away layers can be formed by electrochemical etching. The etched-away layers separate adjacent macroporous layers so that these are preferably self-supporting. In this arrangement an edge region of the semiconductor substrate, which edge region encompasses the macroporous layers at least in part, remains non-etched and is thus used for mechanically stabilizing the encompassed lightly-macroporous layers connected to it. The multilayer stack produced in this manner can subsequently, in a joint fluid process step, as an entity be subjected to further processing steps, for example can be coated with a passivating oxide. Subsequently, the macroporous layers can be separated, successively, from the stabilizing edge region of the semiconductor substrate, wherein a mechanical connection between the macroporous layer and the non-porous edge region is interrupted. Prior to tearing off the respective uppermost layer, processes that have a single-sided effect can be applied. In this way a multitude of thin semiconductor layer substrates in the form of macroporous layers including good surface passivation and a reflection-reducing surface texture can be produced with only a few process steps.

### TECHNICAL FIELD

The invention relates to a method for forming one or several thin semiconductor layer substrates on the basis of which solar cells can be manufactured. Furthermore, the invention relates to a method for manufacturing a solar cell, in which method one or several thin semiconductor layer substrates are formed and are further processed to become solar cells.

### BACKGROUND TO THE INVENTION

The manufacture of solar cells requires high-quality economical semiconductor substrates.

Below, both the technological background and possible characteristics and advantages of the invention are described with reference to the example of forming a semiconductor substrate in the context of manufacturing a silicon solar cell. It should be pointed out, however, that the inventive ideas are not to be restricted to the application of silicon as a semiconductor material; instead, they can generally-speaking also be transferred to other semiconductor materials. The semiconductor layer substrates formed can particularly advantageously be used for manufacturing solar cells because large-scale industrial manufacture of solar cells requires a large number of semiconductor substrates and, for example, material savings as a result of providing thinner substrates can result in considerable reduction in costs.

Conventionally, semiconductor substrates used in the manufacture of solar cells are frequently provided in the form of semiconductor wafers. Most of the time such wafers comprise a thickness of 100-500 μm and are conventionally manufactured by sawing a block of semiconductor material, for example a silicon monocrystal, into thin slices.

In order to be able to reduce costs in the manufacture of solar cells it may be advantageous to provide semiconductor substrates of reduced thickness, for example less than 100 μm and preferably less than 50 μm.

In the state of the art, methods for manufacturing solar cells on the basis of crystalline silicon are known, in which method at first a porous silicon layer is produced on a silicon substrate, and subsequently above the porous silicon layer a further layer of silicon is deposited, for example in an epitaxial manner. This further layer can subsequently be separated from the silicon substrate, wherein the previously produced porous layer is used as a predetermined breaking point. The separated layer can, for example, be made with a thickness of a few μm and can subsequently be used as a thin-film substrate for a solar cell, wherein in the subsequent steps significant components of the solar cell, for example its emitter and/or its contact metallization, can be formed.

Such a method is, for example, described in an article by R. Brendel in Solar Energy, 77, 2004, 969-982 as well as in DE 197 30 975 A1 or U.S. Pat. No. 6,645,833. The method makes use of the fact that the silicon thin film applied to the porous layer preferably grows with the same crystal structure as the silicon substrate that adjoins underneath it. If the silicon substrate is, for example, a high-quality monocrystalline wafer, in this manner a high-quality silicon thin film can be produced which can then be used as the substrate for solar cells with a high efficiency potential.

From DE 42 02 455 C1 a method for the manufacture of a solar cell from a substrate slice is known. In this arrangement a self-supporting semiconductor layer is detached from a monocrystalline silicon wafer by means of electrochemical etching. To this effect, with the use of an acidic fluorine-containing electrolyte, holes are formed in the silicon wafer, and when the holes have reached a depth that essentially corresponds to the thickness of the self-supporting semiconductor layer to be formed, process parameters of etching are changed in such a manner that the self-supporting semiconductor layer automatically detaches as a result of the holes growing together.

However, it has been observed that in the above-described conventional methods for forming thin semiconductor layer substrates significant cost and effort need to be expended in order to produce an individual semiconductor thin film by electrochemically producing a porous semiconductor layer and subsequently detaching the semiconductor layer. Furthermore, it has been shown that handling a thin, self-supporting, porous semiconductor layer and further processing such a semiconductor layer in order to finally manufacture a solar cell from it can be difficult.

### SUMMARY OF THE INVENTION

There may be a need for a method for forming thin semiconductor layer substrates that can subsequently be used as substrates in the manufacture of solar cells, as well as for a method for manufacturing a solar cell, in which methods the above-mentioned problems are at least in part overcome. In particular, there may be a need for a method for manufacturing a solar cell, in which method thin, preferably monocrystalline, semiconductor layers are produced in a simple manner as a substrate for the solar cell, wherein such substrates preferably should comprise both an adequately high electronic quality and a surface texture that is, for example, desirable in the context of a surface of solar cells, and wherein on the basis of such substrates solar cells can be manufactured in a simple and economical manner.

According to a first aspect of the present invention, a method for forming one or several thin semiconductor layer substrates for manufacturing solar cells is proposed. The method comprises the following method-related steps:
(a) providing a semiconductor substrate;
(b1) forming an upper macroporous layer on a partial surface of the semiconductor substrate;
(c1) forming an etched-away layer underneath the macroporous layer;
   wherein the macroporous layer and the etched-away layer are in each case formed by electrochemical etching of the partial surface of the semiconductor substrate in an etching solution;
   wherein an edge region of the semiconductor substrate, which edge region encompasses the partial surface at least in part, remains non-etched in order to form a stabilizing non-porous edge region;
optionally: (b2) forming a further macroporous layer underneath the previously-formed etched-away layer;
optionally: (c2) forming a further etched-away layer underneath the previously-formed macroporous layer; and
(d) subjecting the entire semiconductor substrate, including the macroporous and etched-away layers formed therein, to at least one fluid-method-related step in which a fluid acts on the semiconductor substrate surface;
(e1) mechanically separating the upper macroporous layer from the semiconductor substrate, wherein a mechanical connection between the macroporous layer and the non-porous edge region is interrupted; and
optionally: (e2) mechanically separating the further macroporous layer from the semiconductor substrate, preferably after the upper macroporous layer has been separated from the semiconductor substrate.

In this process the optional steps (b2), (c2) and (e2) can be repeated multiple times.

The present invention can be considered to be based on the following idea.

In a semiconductor substrate, for example a wafer comprising silicon or some other semiconductor material, successively and alternatingly, macroporous layers and etched-away layers can be formed by electrochemical etching. To this effect a partial surface of the semiconductor substrate can be subjected to an etching solution which comprises, for example, hydrofluoric acid. The etching solution successively etches into the semiconductor substrate. Depending on the selection of corresponding influencing parameters such as, for example, an applied voltage or illumination of the semiconductor substrate, as a result of the etching process, layers of different porosity are produced. In order to produce the macroporous layer(s) the influencing parameters can be selected such that a layer of relatively little porosity, for example of less than 40%, is produced. Subsequently the influencing parameters are changed in such a manner that an etched-away layer arises, i.e. a layer in which the pores arising as a result of etching merge, so that a “porosity” of 100%, i.e. a layer in which the semiconductor material has been completely etched away, results. Following etching of the etched-away layer the influencing parameters can again be correspondingly changed in order to produce a further macroporous layer underneath the etched-away layer, etc. In this manner a stack comprising a layer sequence of macroporous layers and adjacent macroporous layers of separating etched-away layers can be produced.

To prevent the adjacent macroporous layers from separating from each other or from the substrate already during the etching process, it is possible, for example, not to subject the entire surface of the semiconductor substrate to the etching solution, but instead only one or several partial surfaces. In an edge region of the semiconductor substrate, which edge region adjoins these partial surfaces, said semiconductor substrate is, for example, protected from the etching solution so that the edge region remains non-etched, thus having no porosity. As an alternative, etching in the edge region can also be prevented in that said edge region during the etching process is in a targeted manner not illuminated. The non-etched edge region can fully or partly enclose the etched partial surface in the manner of a frame, and can, for example, comprise a width of 0.3 to 5 mm. Therefore, both during etching and during subsequent method-related steps, the edge region can hold and stabilize the macroporous layers that are in mechanical connection with it.

The macroporous layers held together by the edge region can subsequently altogether be subjected to further method-related steps. In this process the fact that at this process stage the macroporous layers are still all held by the non-etched edge and are thus stabilized, can be utilized, which can considerably facilitate handling. For example, in one or several shared fluid-method-related step or steps, the characteristic that a fluid of adequately low viscosity can penetrate all the porous layers and can thus reach the entire surface of all the porous layers can be utilized. For example, by means of hot gases one or several dielectric layers can be produced on the surface of the macroporous layers, and thus the surface can be effectively passivated. As an alternative, in a single method-related step, by means of the inflow of hot gases charged with doping agents a doped layer, for example in the form of an emitter, can be produced along the entire surface of all the porous layers.

Subsequently, the individual macroporous layers can be mechanically separated, preferably successively, from the semiconductor substrate in that a mechanical connection between the macroporous layer and the non-porous edge region is interrupted. In each case, prior to detaching an uppermost macroporous layer, an additional method-related step can be carried out in which process parameters are selected in such a manner that only the external surface of the topmost macroporous layer is treated, but not the pores or the opposite surface. In this manner individual macroporous layers can treated on one side. For example, a metal layer used for electrical contacting can be applied on one side.

By means of the described method, with simple processing steps that involve only little processing effort and that if needed can be repeated multiple times, preferably a multitude of thin semiconductor layer substrates can be produced from originally one single semiconductor substrate. Each individual one of these semiconductor layer substrates can comprise one of the macroporous layers. Such semiconductor layer substrates can, in particular because of the porosity of these layers, comprise desired surface texturing without this necessitating additional process steps. In this arrangement the quality of the semiconductor material essentially corresponds to the quality of the semiconductor substrate used as a source material, i.e. if a high-quality semiconductor substrate, for example in the form of a monocrystalline silicon wafer, is used, the produced semiconductor layer substrates, too, will be of a high material quality and in particular will comprise a monocrystalline structure.

Possible characteristics and advantages of embodiments of the method according to the invention are described in more detail below:

The semiconductor substrate provided (process step (a)) can be a substrate comprising any semiconductor material, for example silicon (Si), germanium (Ge), gallium arsenide (GaAs), etc. The semiconductor substrate can be provided in the form of a wafer and can comprise a substantial thickness of several 100 μm. In particular, semiconductor substrates comprising a semiconductor material of high electronic quality, for example a monocrystalline silicon wafer, are preferred. As will be explained in detail later, it has been shown that the method can be advantageously implemented in particular on semiconductor substrates of the n-type semiconductor.

Subsequently, a macroporous layer and an etched-away layer or, as an alternative, in a multiple alternating manner, macroporous and etched-away layers are etched (process steps (b1, b2, . . . ) and (c1, c2, . . . )) into the semiconductor substrate. Preferably, this process starts with the formation of an upper macroporous layer on a surface of the semiconductor substrate, and subsequently underneath this macroporous layer an etched-away layer is etched in.

It should be pointed out that the terms “above” and “underneath” are not to be interpreted as being limiting, and in particular that they do not describe any geometric direction but rather a sequence of forming the individual porous layers, wherein it is assumed that the porous or etched-away layers are successively incorporated into the substrate from top to bottom. During actual processing, the direction of etching can definitely be different from this, for example from the bottom to the top, or from left to right.

The macroporous layers comprise a porosity of less than 60%, more preferably of less than 30%, and further preferably of less than 10%. In this arrangement the term “porosity of a layer” refers to a ratio of the added-up volume of all the pores within a layer to form an overall volume of the layer. In other words, the porosity of a layer is all the greater the more pores there are contained therein and the greater the pores are. An etched-away layer can comprise a porosity of essentially 100%.

The porous layers are produced in the semiconductor substrate by electrochemical etching, for example in that a partial surface of the semiconductor substrate is brought into contact with an etching solution, and simultaneously an electrical voltage is applied between the substrate surface and the etching solution. In other words, the surface of the semiconductor substrate and the etching solution are on different electrical potentials. With suitable polarity of the applied voltage an electrochemical reaction can occur that can result in etching of the substrate surface, in particular locally on nucleation centers. During the electrochemical reaction local oxidizing of the substrate surface and quasi-simultaneous etching-away of the oxidized substrate surface by the wetting etching solution can result. Since, generally-speaking, this process does not take place in a homogeneous manner, but concentrates on clusters, inhomogeneous etching of the substrate surface may occur, in which etching the channels are etched into the substrate largely perpendicularly to the substrate surface, and consequently a porous layer can be formed.

In the production of the first macroporous layer a nucleation phase may be necessary for forming etching seeds, for example in that etching seeds are photolithographically predefined. During etching of a subsequent macroporous layer, seeds can already be present on the surface as a result of the last etching process, and consequently the formation of etching seeds can be saved in subsequent etching processes.

It has been observed that a strength of the electrochemical etching process can, in particular, depend on the number of positive charge carriers (also referred to as “holes” or vacant states in the valence band of the semiconductor material) which are available on the substrate surface. In the case of p-type-semiconductor substrates the holes are the majority charge carriers, and the etching activity during electrochemical etching depends predominantly on the fluorine ion concentration available from the etching solution, and on the electrical voltage applied. In contrast to the above, in the case of an n-type-semiconductor substrate the holes are the minority charge carriers. In the case of such an n-type substrate the quantity of holes available for an electrochemical etching process can be strongly influenced by the illumination of the semiconductor substrate and the associated generation of charge carrier pairs (electrons and holes). In other words, in electrochemical etching of porous layers in n-type substrates, apart from being controlled by the electrical voltage applied, the porosity can be significantly controlled by the intensity of the illumination that takes place concurrently. It has been observed that in the case of n-type substrates it can be necessary to illuminate concurrently with the etching process in order to be able to produce porous layers comprising a macroporous structure.

For the alternating forming of macroporous layers and etched-away layers, the parameters that influence electrochemical etching can thus alternately be set such that the formation of a macroporous layer and the formation of an etched-away layer occur.

For example, in an n-type-semiconductor substrate, by illumination at low light intensity a low etching current and thus low porosity are caused, and consequently only small pores are formed, whereas for the subsequent formation of the etched-away layer the semiconductor substrate is illuminated at a higher light intensity, and consequently greater porosity and thus the formation of larger pores occur, which pores finally merge, thus forming the etched-away layer. Since the pores, for example in a silicon wafer of the 100-crystal direction, always preferably form perpendicularly to the surface of the semiconductor substrate, in this manner a sequence of alternately formed macroporous layers and etched-away layers can be produced. However, in the context of the invention it is not significant for the pore formation to take place perpendicularly to the wafer surface.

Preferably, during electrochemical etching, influencing parameters that influence the intensity and speed of the electrochemical etching process, for example a voltage applied between the semiconductor substrate and the etching solution, an illumination of the semiconductor substrate, a semiconductor type, and a doping concentration within the semiconductor substrate, a concentration of etching substances, for example hydrofluoric acid (HF) within the etching solution, and/or a temperature of the etching solution, are selected in such a manner that the macroporous layer is formed so as to comprise a macroporous structure. According to IUPAC (International Union of Pure and Applied Chemistry), the term “macroporous structure” refers to a layer with an average pore size of more than 50 nm. In the production of solar cells it can be advantageous to form the macroporous substrates with pores whose size ranges from 1 μm to 5 μm. When compared to a mesoporous structure of the same porosity, a coarse macroporous structure in the macroporous layer can provide the advantage of a smaller surface and thus of a lower surface recombination.

Preferably, a wetting agent is added to the etching solution. This wetting agent can make it possible for the actual etching substances of the etching solution to evenly wet the surface of the semiconductor substrate during the etching process. This can, in particular, be advantageous in the extensive channels within the porous layers. It has also been observed that some wetting agents can reduce the viscosity of the etching solution, thus facilitating penetration or circulation of etching solution in already previously etched porous layers. Furthermore, as a result of the wetting agent, gas bubbles that can form during the etching process can easily detach from the surface of the semiconductor substrate. For example ethanol (C₂H₆O) or acetic acid (CH₂H₄O₂) can be used as a wetting agent.

Preferably, during electrochemical etching of the several porous layers, influencing parameters can be adjusted in such a manner that the pore structure and/or the layer thickness of the successively formed macroporous layers essentially remain/remains identical. Since the composition of the etching solution can change in the course of the etching process, and since, in particular, the circulation of etching solution within pores of already etched porous layers can be limited, and thus the exchange of etching solution deeper in the interior of already etched porous layers can be limited, during the successive formation of the different porous layers it may be necessary to adjust the etching parameters, in particular the intensity of illumination of the substrate, during etching in such a manner that the etching rates and thus the resulting etching structures remain essentially unchanged. In this way it can be ensured that the macroporous layers, which later on after mechanical separation are to form the desired thin semiconductor layer substrates, all comprise essentially identical mechanical and electronic characteristics.

Taking into account the etching rate set at the time, the duration of the etching process is preferably selected in such a manner that the macroporous layers are formed with a layer thickness of 5-100 μm, preferably 10-30 μm, whereas the self-supporting layers are only formed with a thickness of 0.5 μm-20 μm, preferably 1 μm-5 μm.

Apart from the possibility of being able to obtain a multitude of thin semiconductor layer substrates in the form of successively separated macroporous layers from a single semiconductor substrate and by means of a contiguous electrochemical etching process with varying etching parameters, the proposed method also makes it possible, prior to mechanical separation of the individual macroporous layers, to subject the multitude of macroporous layers to a common method-related step. In this process it can, in particular, be of interest to subject the already formed porous layers to one or several fluid-method-related steps prior to the mechanical separation of said layers. In this context the term “fluid-method-related step” refers to a method-related step in which a fluid, for example a gas or a liquid, can act on the surface of the semiconductor substrate, in other words, in particular, can act on the outside and on the inside surfaces of the porous layers. By means of such a fluid-method-related step, for example, the entire surface of the porous layers can be coated with an additional layer.

For example, in such a fluid-method-related step a dielectric layer can be formed on the surfaces of the macroporous layers and of the etched-away layers. The dielectric layer can, in particular, be used for passivation of the surfaces.

In a concrete embodiment the semiconductor substrate with the macroporous and etched-away layers that have previously formed therein can be subjected to a high-temperature process step in which at temperatures of above 450° C., preferably of above 700° C., for example in an oxygen-containing atmosphere a silicon dioxide layer (SiO₂) homogeneously grows on the surfaces of the porous layers. Such a silicon dioxide layer can already at thin layer thicknesses of less than 10 nm result in effective surface passivation of the porous layers.

As an alternative, by means of the fluid-method-related step it is also possible, for example, for a silicon nitride layer or an aluminum oxide layer for passivating the surface to be deposited. An aluminum oxide layer can, for example, be deposited by means of an atomic layer deposition method (ALD method) at deposition temperatures of below 500° C., preferably below 250° C. As a further alternative, in the context of a gas phase diffusion step a layer in the vicinity of the surface can be doped with dopants, for example phosphorus or boron.

In a further embodiment of the method according to the invention, preferably in each case prior to releasing one or several macroporous layers from the frame-like edge region, a thin layer is applied only to parts that lie on the outside of the respectively uppermost macroporous layer by means of a gas deposition process such as, for example, a plasma deposition process and/or a sputter depositing process. For example, a thin aluminum layer that can serve as a metal contact for a solar cell can be deposited in a sputter depositing process, or a thin silicon nitride layer, which can be used as a barrier during a subsequent diffusion or a wet-chemical process, can be deposited by means of a plasma deposition process, for example plasma enhanced chemical vapor deposition (PECVD).

Both in the case of plasma deposition processes and in the case of sputter depositing processes, particles from a gas phase can be deposited on a surface to be coated. One difficulty in the coating of porous layers can consist of the layers being perforated by the pores. Since, as a rule, solar cells are to be processed only rarely on both sides, but often only on one side, in this case it must be ensured that the other side of the cell in fact remains unprocessed. In order to achieve this, during the gas deposition process an adequately low gas pressure can be selected so that depositing a thin layer on interior surfaces of the porous semiconductor layer substrate is largely prevented. in other words, a gas pressure can be selected that is low enough for the free paths of particles within the gas to be sufficiently large for the particles essentially no longer to be able to enter the pores of the porous layer, and consequently only coating of the outer regions of the porous layer occurs, while interior regions of the porous layer remain, however, largely uncoated. As an alternative, treatment with a viscous fluid that cannot enter the pores can take place. The porous layer is then treated only on one side.

In order to mechanically separate a macroporous layer situated on the outside from the semiconductor substrate, for example a mechanical force can be exerted directly on the macroporous layer. For example, the macroporous layer can be gripped with the use of a vacuum suction device, and by a suitable movement of the vacuum suction device relative to the semiconductor substrate can be broken off from the semiconductor substrate. In this process the geometry of the vacuum suction device and the movement of the vacuum suction device can be adjusted in such a manner that the macroporous layer breaks at a junction to the stabilizing, non-etched, edge region. In this manner, the previously produced macroporous layers, stacked on top of each other, can, successively and each one individually, be gripped by the vacuum suction device, can be broken off, and can be fed to subsequent processing steps.

In order to support separation, from the semiconductor substrate, of a macroporous layer situated on the outside, in a circumferential region of the macroporous layer a trench can be formed. The trench can, for example, be produced by means of a laser or a mechanical chip saw. The depth of the trench can approximately correspond to the thickness of the macroporous layer to be separated, or the depth can be less than said thickness so that the macroporous layer can be removed in a controlled manner. The trench can be formed in an entire circumferential region or in parts of a circumferential region of the macroporous layer, i.e., for example, where the macroporous layer laterally borders the adjoining stabilizing edge region.

As an alternative, a macroporous layer, which is situated on the outside, can be mechanically separated from the semiconductor substrate in that a carrier substrate is made to adhere to the macroporous layer that is situated on the outside, and the carrier substrate with the macroporous layer situated on the outside, which macroporous layer adheres to said carrier substrate, is then torn from the semiconductor substrate. For this purpose a method as is, for example, used in module encapsulation can be used, or a sol-gel method can be used.

Preferably a flexible foil, for example an aluminum foil, can be used as a carrier substrate. The foil, together with the outer macroporous layer adhering to it, can then be torn from the underlying layer by an unrolling pulling action. In this manner the mechanical stress can be concentrated in the respective uppermost macroporous layer that adheres to the foil, and in the adjoining highly-porous layer, and layered detachment of the macroporous layers can be facilitated. Adhesively applying the flexible foil can take place, for example, by heating in an oven or by laser irradiation. After the heating process the silicon can be doped with atoms from the foil, and consequently it is possible to combine the manufacture of the pn-junction with adhesively applying the foil.

According to a further aspect of the present invention, a method for manufacturing a solar cell is proposed. Apart from possible further process steps, the method comprises the following process steps: (i) forming a thin semiconductor substrate by means of the method described above; (ii) forming doped regions in the semiconductor layer substrate; and (iii) forming electrical contacts on surface regions of the semiconductor layer substrate.

It should be noted that the embodiments, characteristics and advantages of the invention have been described in part with reference to the method for forming thin semiconductor layer substrates, as can be used in a manufacturing process for solar cells, and in part with reference to the method according to the invention for manufacturing a solar cell, and partly also with reference to the manufactured semiconductor thin-film substrates or solar cells. The average person skilled in the art will recognize that the characteristics of the various embodiments can be combined among each other at will, and that the described method-related characteristics can require corresponding structural characteristics in the manufactured semiconductor thin-film substrates or semiconductor devices or vice versa.

### BRIEF DESCRIPTION OF THE DRAWINGS

Further possible characteristics and advantages of the present invention will be evident to the average person skilled in the art from the following description of exemplary embodiments, which are, however, not to be interpreted as limiting the invention, and with reference to the accompanying drawings.

FIG. 1 shows an arrangement by means of which the method for forming semiconductor thin-film substrates according to one embodiment of the invention can be implemented.

FIG. 2 shows an alternative arrangement by means of which the method for forming semiconductor thin-film substrates according to one embodiment of the invention can be implemented.

FIG. 3 shows a sequence of steps of a method for forming semiconductor thin-film substrates according to one embodiment of the invention.

FIG. 4 shows a diagrammatic top view of a semiconductor substrate in which a macroporous layer encompassed by an edge region has been produced by means of a method according to one embodiment of the present invention.

FIG. 5 shows an electron microscope image of a porous silicon layer structure that can be produced with a method according to one embodiment of the invention, and in which structure the individual layers are separated from each other by intermediate etched-away layers.

FIG. 6 shows an enlarged electron microscope image of a silicon layer substrate that was formed by means of a method according to one embodiment of the invention.

The drawings are merely diagrammatic and are not to scale. Same reference characters in the figures refer to identical or similar elements.

### DETAILED DESCRIPTION OF PREFERRED EMBODIMENTS

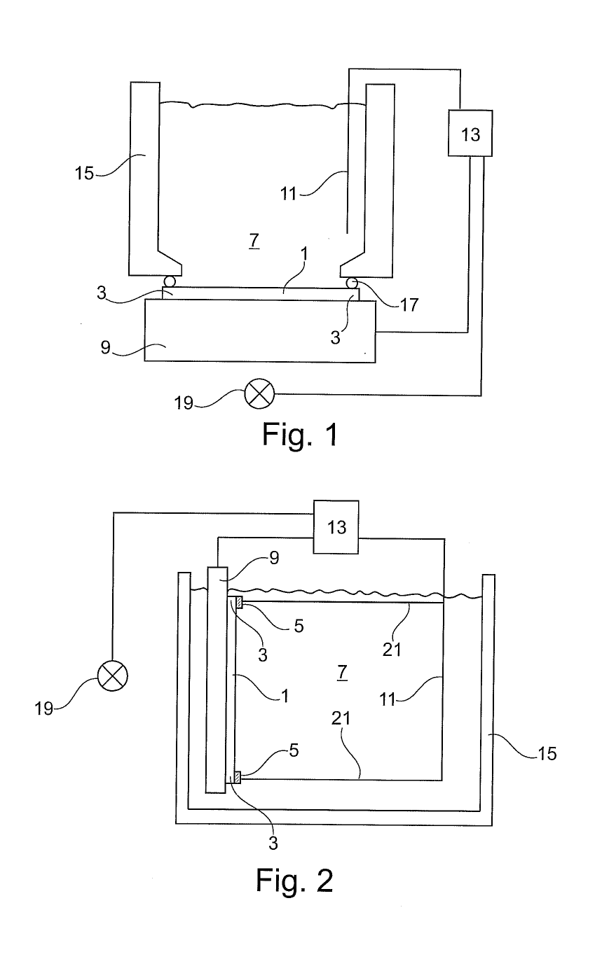

At first, with reference to FIGS. 1 and 2, devices are presented by means of which devices embodiments of the method according to the invention for forming semiconductor thin-film substrates can be implemented.

In the device shown in FIG. 1, a semiconductor substrate 1 rests horizontally on an electrode 9. The electrode 9 comprises an acrylic glass plate above which thin platinum wires have been tensioned. Thus the electrode 9 is largely transparent. A vessel 15 that is open at the top and at the bottom comprises a 1-5% hydrofluoric acid-etching solution 7. As a result of a sealing O-ring 17 arranged between the bottom of the vessel 15 and the semiconductor substrate 1, any leaking out of etching solution 7 is prevented. Furthermore, the O-ring 17 prevents etching solution 7 from coming into contact with an edge region 3 of the semiconductor substrate. A second electrode 11 is immersed in the etching solution 7. The two electrodes 9, 11 are connected to a control device 13, wherein the control device 13 can vary a voltage that is present between the electrodes 9, 11. Underneath the vessel 15 a lamp 19 is arranged in order to illuminate from the back the semiconductor substrate 1 through the largely transparent first electrode 9. The lamp 19 is also connected to the control device 13, wherein the control device 13 is designed to vary the brightness or the intensity of the radiated light of the lamp 19.

In the alternative device shown in FIG. 2, a hydrofluoric acid-containing etching solution 7 is contained in a vessel 15. A semiconductor substrate 1 rests vertically against a first electrode 9. Both the first electrode 9 and a second platinum electrode 11 are immersed in the etching solution 7. Both electrodes 9, 11 are connected to a voltage-supplying control device 13. A tunnel 21 is used to homogenize the electrical field extending between the two electrodes 9, 11. A lamp 19 is used for illuminating the semiconductor substrate 1 from the back through the largely transparent first electrode 9, with the brightness of said lamp 19 being able to be varied by means of the control device 13. An edge region 3 of the semiconductor substrate 1 has been protected by a varnish layer 5 prior to immersion in the etching solution 7, and in this manner the etching solution 7 is prevented from establishing contact with the edge region 3.

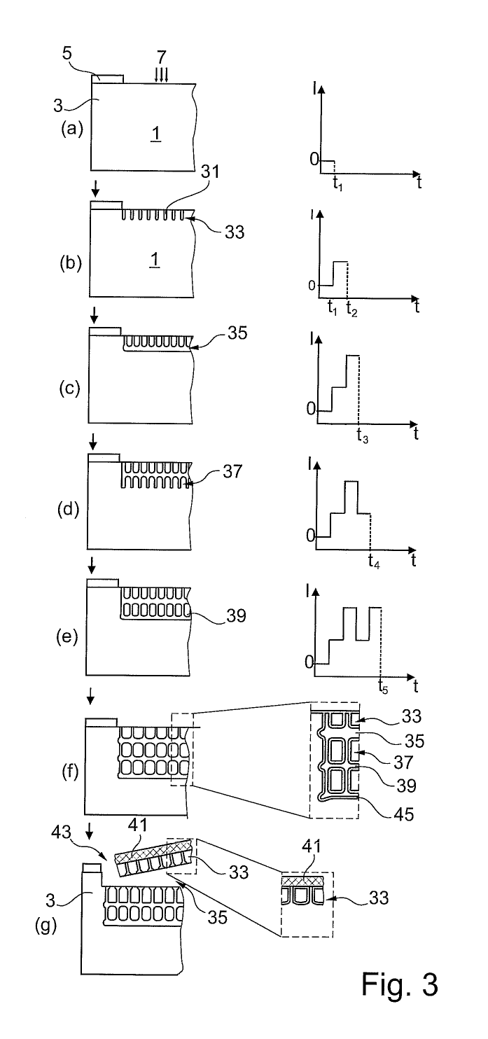

With reference to FIG. 3, method-related steps (a) to (e) of a method for forming thin semiconductor layer substrates according to one embodiment of the invention are to be described. In this arrangement in each case the left-hand side shows a diagrammatic view of the current state of the semiconductor substrate 1 used, while the right-hand side shows a chronological sequence of the intensity of the light radiated by the lamp 19 onto the semiconductor substrate 1.

It should be noted that, because of the radiated-in light, positive charge carriers, in other words “holes”, are produced in the n-conducting silicon wafer used as a semiconductor substrate 1. The more holes there are available in the semiconductor substrate, the greater the etching current can be that flows through the semiconductor substrate 1, which etching current flows due to the voltage applied between the two electrodes 9, 11. The provided radiated-in light intensity I is a direct measure of the currently flowing etching current and thus of the currently etched porosity, which is set by the etching solution 7 in the region near the surface of the semiconductor substrate 1.

In the illustrations shown in FIG. 3, in each case a region of a partial surface of a semiconductor substrate 1 is shown, which region is wetted by the etching solution 7, and which region adjoins the edge region 3 that is not to be etched. In this arrangement the edge region 3 is protected, by a protective layer 5, from the etching solution 7.

In a first step (a) a semiconductor substrate 1 in the form of an n-type-silicon wafer of the crystal direction 100 is provided, and on a partial surface of its upper surface is made to contact the etching solution 7. Since so far no light from the lamp 19 has yet been radiated-in onto the wafer 1, the etching current between the electrodes 9, 11 and thus the etching intensity is at first negligible.

In step (b) at the point in time t₁ the lamp is switched on and at first is kept at low light intensity for between approximately 1 and 60 minutes. During this phase a low etching current with a typical current density ranging from 1 to 10 mA/cm² arises. The voltage applied between the electrodes 9, 11 ranges from 0.5 to 5 V. In this arrangement the etching process commences at the surface of the semiconductor substrate 1, which surface is in contact with the etching solution 7, in regions that were either defined beforehand, for example by means of photolithography, in that adjacent regions were protected by means of an etching-barrier layer, or in which regions natural seeds exist on the substrate surface 1. Because of the hitherto only low etching current, during this etching phase narrow channels 31 at a diameter of approximately 0.5 to 5 μm are etched into the substrate surface. The channels extend largely perpendicularly to the surface of the substrate 1. As a result of etching-in the narrow channels 31, a first, upper, macroporous layer 33 is generated. The time span during which the illumination and thus the etching current are kept so low is selected in such a manner that the thickness of the produced macroporous layer 33 corresponds to a desired thickness of a semiconductor layer substrate to be formed. Typical aimed-at thicknesses range from 10 to 50 μm. Typical etching durations for this are 1 to 60 min, for example 10 to 60 min.

In the next method-related step (c) the light intensity I radiated-in by the lamp 19 is increased. In this arrangement the light intensity can be increased, abruptly or successively, over a period of time of a few minutes, wherein by means of the type of the increase a resulting surface structure of the produced porous layer can be influenced. Because of the increased number of available generated charge carriers in the semiconductor substrate 1 a higher etching current and thus an increased rate of etching occur. It has been shown that in such an increased rate of etching the etching process no longer progresses primarily perpendicularly to the surface of the substrate 1, but also across it. Therefore the diameter of the etched-in channels increases to such an extent that adjacent channels or pores merge. An etched-away layer 35 is formed. In this etched-away layer 35 no semiconductor material remains in the regions between adjacent etched channels. Thus, the etched-away layer 35 separates the macroporous layer 33 situated above from the substrate 1 that remains below it, and consequently the macroporous layer 33 is self-supporting and connected to the substrate 1 only by way of the edge region 3.

In a further method-related step (d) the illumination intensity is reduced anew so that again thinner channels form, and a further macroporous layer 37 arises.

Subsequently, in a method-related step (e) the illumination intensity can again be increased, and a further etched-away layer 39 can be formed.

The method-related steps (d) and (e) can be repeated multiple times so that a layer sequence of macroporous layers and adjoining etched-away layers results.

Since the circulation of etching solution in the narrow channels of the porous layers can be impaired with increased depth of the channels, and thus the rates of etching can be reduced, corresponding measures can be taken to provide also the macroporous and etched-away layers situated deeper down with a similar structure and thickness to the layers situated further up. For example, a wetting agent can be added to the etching solution, the light intensity or the etching durations can be correspondingly adjusted, or the concentration of the etching solution used can be varied.

After the desired structure of several adjoining macroporous layers and etched-away layers in the semiconductor substrate has been formed, said semiconductor substrate is removed from the etching solution, is rinsed and cleaned in de-ionized water, and is subsequently dried. In this arrangement the fact that the several self-supporting macroporous layers stacked on top of each other are all connected to the non-etched edge region 3 and are mechanically stabilized by said edge region 3 is used to advantage. The stack of macroporous layers can thus together with the remaining non-etched semiconductor substrate be further processed in a simple manner as an entity.

For example, in a shared fluid-method-related step (f) the entire semiconductor substrate, including the layer structures etched into it, can be subjected to a high-temperature step in which the semiconductor substrate is exposed to an oxygen-containing gas atmosphere at high temperatures of more than 450° C. At these high temperatures the surface of the silicon substrate is oxidized, and a thin silicon dioxide layer 45 (SiO₂) forms. Since the hot oxygen-containing gas can without any problems also penetrate into the voids of the porous or etched-away layers 33, 35, 37, 39, the entire surface of the porous layers is covered by a thin oxide layer 45 with a thickness of a few nm. The thin oxide layer can act as surface passivation. The surface of the porous or etched-away layers 33, 35, 37, 39, which surface is greatly increased because of the porous structure, is thus well-protected against recombination, which would otherwise occur more frequently in that location. Investigations have shown that silicon substrates in which a porous layer has been surface-passivated in this manner comprise similarly high charge-carrier life times and thus a similarly high electronic quality as does the monocrystalline silicon wafer material that is used as the source material.

As an alternative to the described oxidation process, other fluid-method-related steps can also be carried out. In each case advantage can be taken of the fact that on the one hand the hitherto not yet mechanically subdivided stack of macroporous layers 33, 37 and etched-away layers 35, 39 situated in-between can in a simple manner be handled as an entity, and in that, on the other hand, the fluid can in a simple manner penetrate into the entire porous structure, and thus all the macroporous layers stacked on top of each other can be treated in a similar manner. Alternative fluid-method-related steps can, for example, comprise gas phase diffusion, atomic layer deposition, or wet-chemical treatment.

Since the fluid-method-related step can jointly be implemented concurrently on a multitude of porous layers formed on the semiconductor substrate, and these layers can subsequently, in the state pre-processed by the fluid-method-related step, be further processed to become finished solar cells, by means of the method proposed in the present document the throughput in the manufacture of solar cells can be significantly improved.

In a subsequent method-related step (g) the individual macroporous layers 33, 37 are then, preferably successively, mechanically separated from the semiconductor substrate 1. To this effect it is possible, for example, to adhesively apply a carrier substrate 41 to an uppermost macroporous layer 33. The carrier substrate 41 together with the macroporous layer 33 adhesively applied thereto can then be subjected to a mechanical force so that the macroporous layer 33 breaks in a circumferential region 43 near the edge region 3, and thus can be detached from the semiconductor substrate 1. The carrier substrate 41 can be selected in such a manner, for example as a transparent glass plate, that it can also during subsequent method-related steps, or during subsequent use of the macroporous layer as a solar cell, continue to be used as a carrier substrate. As an alternative, in a subsequent method-related step the carrier substrate 41 can be detached again from the macroporous layer 33.

The method-related step (g) of separating the topmost macroporous layer can be repeated multiple times until all the previously produced macroporous layers 33, 37 have been separated from the semiconductor substrate 1.

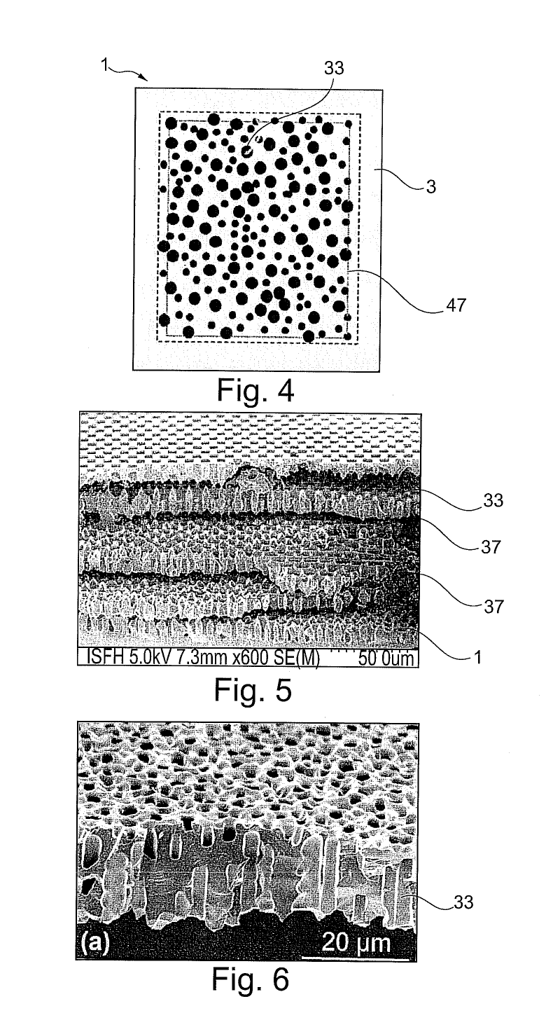

FIG. 4 diagrammatically shows a top view of a semiconductor substrate 1 in which a macroporous layer 33 has been etched into a frame-like edge region 3, which remains non-etched. In order to be able to subsequently remove the macroporous layer 33 a trench 47 is made in the vicinity of the edge region 3 by means of a laser or a chip saw. The depth of the trench 47 approximately corresponds to the thickness of the macroporous layer 33, so that the latter can subsequently be separated from the semiconductor substrate 1 without any problems.

FIG. 5 shows an electron microscope image of a silicon substrate on whose surface several macroporous layers 33, 37 that are situated on top of each other, and in each case etched-away layers 35, 39 that are arranged between adjacent macroporous layers, are evident. The figure shows an oblique top view of a break of a macroporous sample with regularly arranged pores, wherein, prior to etching, on one surface of a silicon wafer that serves as a starting substrate, a chessboard-like pattern has been defined by means of photolithography.

FIG. 6 shows an electron microscope image of an individual, detached, macroporous layer 33 as can subsequently be used as a semiconductor layer substrate for further processing to form a thin solar cell. The macroporous structure with pores at a magnitude of a few μm is clearly shown. At the same time, because of the distributed pores, the surface of the macroporous layer comprises a certain surface texture which if used as a substrate for a solar cell can cause a desired reduction in reflection loss. Because of the nature of the manufacturing method, this surface texture is automatically generated in the formation of the macroporous layer; it does not require any additional method-related steps.

There are many process variants for manufacturing solar cells from previously surface-treated semiconductor layer substrates within the framework of a fluid-method-related step. Among other things the precise process can depend on the nature of the surface treatment.

If the surface treatment is a phosphorus diffusion in the surface of an n-type macroporous silicon semiconductor layer substrate, then, for manufacturing a solar cell, one of the two sides at least locally also requires a p-type contact, which advantageously overcompensates for the phosphorus diffusion underneath the contact. This can take place by means of aluminum, applied either locally or across an extensive area, preferably in combination with detachment of the individual layers. The phosphorus diffusion can be contacted by means of a conductive transparent oxide or by means of a metal.

If the surface treatment comprises depositing an Al₂O₃-layer, then, as a result of electrical charges integrated in the Al₂O₃-layer, a current-collecting induced pn-junction arises that can be contacted by means of a tunnel contact or by means of local p-type diffusion. In this case on one of the two sides a contact to the n-type macroporous silicon is yet to be produced. This can take place, for example, by laser doping an n-type layer onto parts of one side.

Single-side processing of macroporous layers is associated with a basic problem in that the pores harbor a risk of the processes reaching through the pores, thus always acting on both sides of the macroporous layer. However, because a solar cell has to be a non-symmetrical component which comprises, for example, p-type and n-type regions, processes that have a single-sided effect will always be required.

In order to make possible single-sided processes in a targeted manner, preferably prior to removing the surface-treated macroporous semiconductor layer substrates from the frame-like edge region a deposition process can be used that takes place at low pressure of, for example, less than 100 Pa. The deposition pressure prevents deposition in the depth of the pores and on the rear of the macroporous layer situated on the outside. In this manner single-sided processing of porous layers becomes possible, which is useful in the manufacture of solar cells from surface-treated layers.

Deposition of an aluminum layer is one such imaginable process. The aforesaid deposition, at high temperature in the so-called fire step, generates a p-type region that can be used as an emitter. In addition, the aluminum layer at the top of the topmost porous layer mechanically stabilizes said aluminum layer, which facilitates homogeneous detachment of large layers. As an alternative, the aluminum layer can also be applied by way of a screen printing process; wherein the subsequent process steps do not change as a result of this.

As an alternative, single-sided processing is also possible as a result of applying viscous coating compounds or viscous etching solutions that are too viscous to penetrate the pores. This can arise on a layer-by-layer basis, in each case prior to removing the layers from the frame.

Finally it should be pointed out that terms such as “comprising” etc. do not exclude the presence of further elements. Nor do the terms “a” or “one” exclude the presence of a multitude of objects. Reference characters in the claims are only provided for improved readability; they are not to be interpreted as limiting the scope of the claims in any way.

### LIST OF REFERENCE CHARACTERS

1 Semiconductor substrate
3 Edge region
5 Protective layer
7 Etching solution
9 First electrode
11 Second electrode
13 Control device
15 Vessel
17 O-ring
19 Lamp
21 Tunnel
31 Channel
33 Macroporous layer
35 Etched-away layer
37 Macroporous layer
39 Etched-away layer
41 Carrier substrate
43 Circumferential region
45 Dielectric layer
47 Trench

1. A method for forming at least one thin semiconductor layer substrate for manufacturing solar cells, wherein the method comprises:
(a) providing a semiconductor substrate;
(b1) forming an upper macroporous layer on a partial surface of the semiconductor substrate;
(c1) forming an etched-away layer underneath the macroporous layer wherein the macroporous layer and the etched-away layer are in each case formed by electrochemical etching of the partial surface of the semiconductor substrate in an etching solution, wherein an edge region of the semiconductor substrate, which edge region encompasses the partial surface at least in part, remains non-etched in order to form a stabilizing non-porous edge region;
(d) subjecting the entire semiconductor substrate, including the macroporous and etched-away layers formed therein, to at least one fluid-method-related step in which a fluid acts on the semiconductor substrate surface, wherein a thin layer on outside regions of a macroporous layer is formed by a gas deposition process, wherein a gas pressure is selected to be adequately low so that depositing a thin layer on interior surfaces of the porous semiconductor layer substrate is largely prevented; and
(e1) mechanically separating the upper macroporous layer from the semiconductor substrate, wherein a mechanical connection between the macroporous layer and the non-porous edge region is interrupted.

2. The method according to claim 1, further comprising:
(b2) forming a further macroporous layer underneath the previously-formed etched-away layer;
(c2) forming a further etched-away layer underneath the previously-formed macroporous layer,
wherein the further macroporous layer and the further etched-away layer are in each case formed by electrochemical etching of the partial surface of the semiconductor substrate in an etching solution; and
(e2) mechanically separating the further macroporous layer from the semiconductor substrate, preferably after the upper macroporous layer has been separated from the semiconductor substrate.

3. The method according to claim 2, wherein the method-related steps (b2) and (c2) are repeated multiple times.

4. The method according to claim 2, wherein the entire semiconductor substrate, including several macroporous and etched-away layers formed therein, prior to the method-related step (e) is subjected to the fluid-method-related step in which a fluid acts on the semiconductor substrate surface.

5. The method according to claim 1, wherein in the fluid-method-related step the entire semiconductor substrate, including macroporous and etched-away layers formed therein, is subjected to an oxygen-containing atmosphere in a high-temperature step at a temperature of at least 450° C.

6. The method according to claim 1, wherein in the fluid-method-related step the entire semiconductor substrate, including macroporous and etched-away layers formed therein, is subjected to atomic layer deposition for the deposition of an aluminum oxide layer at a temperature of below 500° C.

7. The method according to claim 1, wherein in the fluid-method-related step the entire semiconductor substrate, including macroporous and etched-away layers formed therein, is subjected to a high-temperature step in a dopant-containing atmosphere at a temperature of at least 700° C.

8. The method according to claim 1, wherein during electrochemical etching of the several macroporous and etched-away layers influencing parameters can be adjusted in such a manner that the pore structure and the layer thickness of the successively formed macroporous layers essentially remain identical.

9. (canceled)

10. The method according to claim 1, wherein in order to support separation of a macroporous layer, which is situated on the outside, from the semiconductor substrate a trench is formed in a circumferential region of the macroporous layer.

11. The method according to claim 1, wherein a macroporous layer, which is situated on the outside, is mechanically separated from the semiconductor substrate in that a carrier substrate is made to adhere to the macroporous layer that is situated on the outside, and the carrier substrate with the macroporous layer situated on the outside, which macroporous layer adheres to said carrier substrate, is then torn from the semiconductor substrate.

12. The method for manufacturing a solar cell, comprising:
forming a thin semiconductor layer substrate by means of a method according to claim 1;
forming doped regions in the semiconductor layer substrate; and
forming electrical contacts on surface regions of the semiconductor layer substrate.
